(19) United States
(12) Patent Application Publication
(10) Pub. No.: US 2012/0126560 A1
(43) Pub. Date: May 24, 2012

(54) EXTENSION POLE SYSTEM FOR RECEIVING A PLURALITY OF BATTERY-POWERED TOOLS

(76) Inventor: John Ockleston, Pacific, MO (US)

(21) Appl. No.: 13/299,470

(22) Filed: Nov. 18, 2011

Related U.S. Application Data
(60) Provisional application No. 61/415,462, filed on Nov. 19, 2010.

(51) Int. Cl. B66F 19/00; H05K 13/00; B23P 11/00

(52) U.S. Cl. 294/210; 294/209; 29/428; 29/592.1

(57) ABSTRACT

An extension pole system for receiving a plurality of tools is provided. The system includes an extension pole having a first end and a second end, and a mounting bracket coupled to the first end of the extension pole. A clamping member is releasably couplable to the mounting bracket to secure a tool between at least the clamping member and the mounting bracket. A trigger actuator is rotatably coupled to the mounting bracket and is operable to actuate the trigger of the tool secured between the clamping member and the mounting bracket. The mounting bracket and the clamping member are adjustable for receiving a plurality of different tools.

### CROSS-REFERENCE TO RELATED APPLICATION

This application claims priority to U.S. Provisional Patent Application No. 61/415,462 filed Nov. 19, 2010, the entire disclosure of which is hereby incorporated by reference in its entirety.

### BACKGROUND

The invention described herein relates generally to an extension pole system for receiving a plurality of battery-powered tools, and more specifically, to an extension pole having an adjustable mounting bracket at a first end for receiving a variety of different battery-powered tools, and a housing disposed at another end of the extension for receiving a battery to power the variety of different power tools.

Oftentimes, a user desires to use a handheld power tool to drill, cut, grind, or otherwise act upon an object that is out of arm's reach. In some instances, the object may be vertically and/or horizontally spaced from the user such that the object is out of reach and the user cannot act upon the object with the power tool. In order to reach the object, the user must then either position themselves nearer the object (e.g., by climbing a ladder, scaffold, or other similar structure) or position the object nearer to their location. Either or both of these solutions may be difficult or unsatisfactory because of the position, location, and/or size of the object.

Some known specialty power tools have attempted to solve this problem by incorporating an extension pole into the tool. Such tools have a head with a blade, drill bit, or other mechanism disposed at one end of the pole and a handle disposed at another, opposing end of the pole. The user is thus able to act upon objects with the tool that would otherwise be out of arm's reach. One example of these tools is a tool (i.e., a pole saw/pruner) with a chainsaw blade attached to a first end of a pole and a gas engine connected to a second, opposing end of the pole. Many users, however, are either unwilling or unable to purchase a specialty tool that substantially replicates the functionality of another tool.

Accordingly, it would be desirable to have a system for coupling a conventional battery-powered tool (or other power tool) to an extension pole such that the tool is positioned adjacent one end of the pole while the tool is controllable by a user from another, opposing end of the pole.

This section is intended to introduce the reader to various aspects of art that may be related to various aspects of the disclosure, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

### BRIEF SUMMARY

One aspect is an extension pole system for receiving a plurality of different power tools. The system comprises an extension pole having a first end and a second end, a mounting bracket coupled to the first end of said extension pole, said mounting bracket having a base plate, and a clamping member releasably couplable to said mounting bracket to secure a power tool between at least said clamping member and the mounting bracket, where at least one of said mounting bracket and said clamping member are adjustable for receiving a plurality of different power tools.

Another aspect is a pole system for receiving a plurality of different tools. The system comprises a pole having a first end and a second end, a mounting bracket coupled to the first end of said pole, and a clamping member releasably couplable to said mounting bracket to secure a tool between at least said clamping member and said mounting bracket, wherein said mounting bracket and said clamping member are adjustable for receiving a plurality of different tools.

Yet another aspect is a method of securing a tool in a pole system for receiving a plurality of different tools. The system comprises a pole having a first end and a second end, a mounting bracket coupled to the first end of the pole, and a clamping member releasably couplable to the mounting bracket to secure the tool between at least the clamping member and the mounting bracket. At least one of the clamping member and the mounting bracket are adjustable to received a plurality of different tools. The method comprises the steps of mounting the tool in the clamping member and the mounting bracket, positioning a trigger actuator connected to the mounting bracket against a trigger of the tool, wherein the trigger actuator is positionable between a first position where the actuator does not actuate the trigger of the tool and a second position where the actuator acts against the trigger, and pulling a cord coupled to the trigger actuator, wherein pulling of the cord moves the trigger actuator to the second position and the actuator acts against the trigger of the tool to actuate the tool.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIGS. 1-9 show exemplary embodiments of a system for coupling a power tool to an extension pole.

FIG. 1 is a top plan view of an exemplary embodiment of a system for coupling a power tool to an extension pole.

FIG. 2 is a top plan view of the system for coupling a power tool to an extension pole of FIG. 1 showing a different type of power tool.

FIG. 3 is an expanded side view of a mounting bracket and clamping member used to couple a power tool to an extension pole in the exemplary embodiment of FIG. 1.

FIG. 4 is an isometric view of the mounting bracket and clamping member of FIG. 3.

FIG. 5 is an isometric view of side plates used in the mounting bracket of FIG. 3 and the clamping member of FIG. 3.

FIG. 6 is an isometric view of the base plate of the mounting bracket of FIG. 3 and a trigger actuator coupled to the base plate.

FIG. 7 is a partial cut-away side view of a housing positioned adjacent a second end of the extension pole.

FIG. 8 is a partial cut-away top plan view of the housing of FIG. 7.

FIG. 9 is a top plan view of another embodiment of a mounting bracket and clamping member used to couple a power tool to an extension pole in the exemplary embodiment of FIG. 1.

Corresponding reference characters indicate corresponding parts throughout the several views of the drawings.

### DETAILED DESCRIPTION OF THE INVENTION

The following detailed description illustrates the disclosure by way of example and not by way of limitation. The description clearly enables one skilled in the art to make and use the disclosure, describes several embodiments, adaptations, variations, alternatives, and use of the disclosure, including what is presently believed to be the best mode of carrying out the disclosure.

The embodiments described herein are generally directed to an extension pole system for receiving (i.e., coupling) a plurality of different battery-powered tools. More specifically, the system enables the coupling of a battery-powered tool (referred to herein interchangeably as a “tool” or a “power tool”) to a first end of an extension pole and the remote positioning of a battery used to power the tool near a handle disposed at an opposing, second end of the pole. The tool may be any battery-powered tool, such as a reciprocating saw, a circular saw, or a drill. Moreover, the system is operable to receive both a plurality of different types of tools and a plurality of tools manufactured by different manufacturers. In some embodiments, the tool may be an electrically powered tool that does not use a battery (e.g., a corded power tool). Furthermore, the tool may be a pneumatically or hydraulically powered tool in some embodiments. While reference is made herein to battery-powered tools or power tool, it should be understood that these other types of tools may be used in the system as well.

The system includes a mounting bracket coupled to the pole adjacent the first end thereof. The mounting bracket includes a clamping member configured to couple a variety of different battery-powered tools to mounting bracket. The mounting bracket also includes a trigger actuator for actuating a trigger and/or switch used to control operation of the battery-powered tool. The trigger actuator is remotely controllable by a user positioned near the second end of the pole with a rope, linkage or other similar structure.

A battery used to power the tool is positioned adjacent the second end of the pole. The battery is electrically coupled to the tool by one or more wires and/or cables. In some embodiments, the length of the extension pole is changeable (e.g., the pole is a telescoping pole) and a cable spool positioned adjacent the second end of the pole is used to store and dispense the wires and/or cables used to electrically couple the tool to the battery. The cable spool may be positioned in a housing adjacent the second end of the pole.

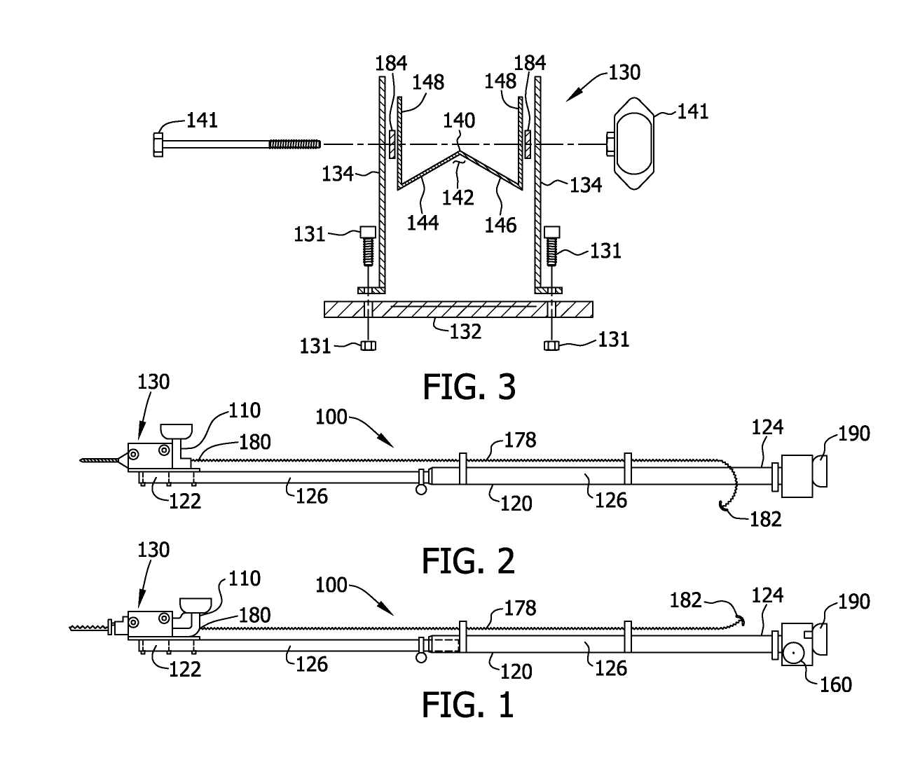

Referring now to the drawings and FIGS. 1-4 in particular, FIG. 1 depicts an exemplary embodiment of a system, referred to generally at 100, for coupling a battery-powered tool 110 to an extension pole 120. The system 100 also includes a mounting bracket 130, a clamping member 140, a trigger actuator 170, and a cable spool 200, each of which is described in greater detail below.

The extension pole 120 (referred to herein interchangeably as a “pole”) has a first end 122 and an opposing, second end 124. In one embodiment, the length of the extension pole 120 may be anywhere between about 2 feet to more than 30 feet. In some embodiments, the extension pole 120 includes a plurality of sections 126 and is telescoping in nature such that the length of the pole 120 can be adjusted. The extension pole 120 is formed from any suitable material, such as, but not limited to, steel, aluminum, fiberglass, or any other suitably rigid material. The pole 120 may also have a hollow interior cavity.

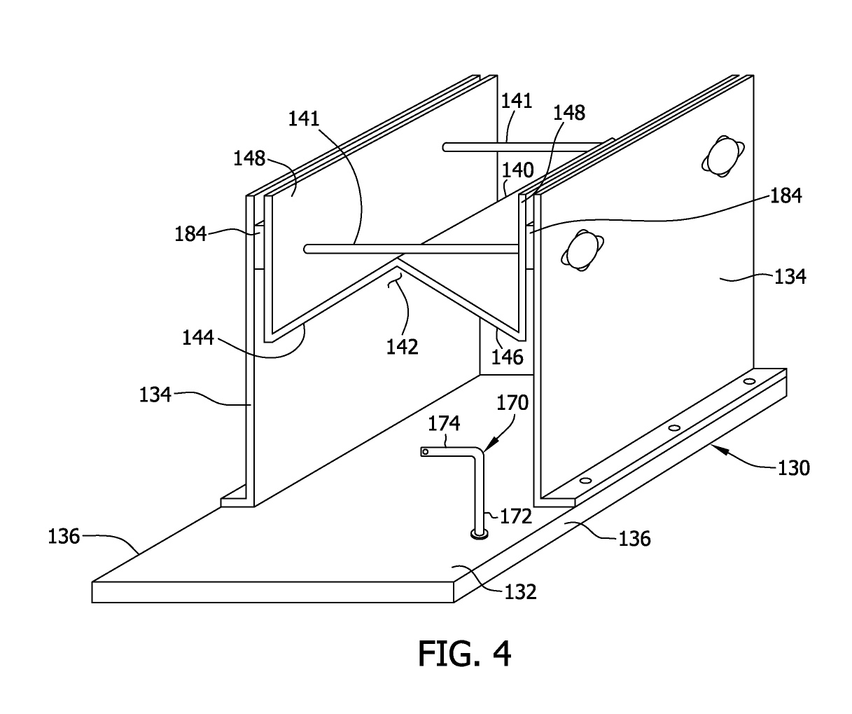

The mounting bracket 130 is coupled to the first end 122 of the pole 120 by any suitable fastening system (e.g., mechanical fasteners, adhesive bonding, and/or welding). In one embodiment, the mounting bracket 130 and clamping member 140 are used to couple a main body of the tool 110 to the first end of the pole 120. As best seen in FIGS. 3 and 4, the mounting bracket 130 has a base plate 132 with a pair of side plates 134 disposed at opposing edges 136 of the base plate 132. A trigger actuator 170 is rotatably coupled to the base plate 132 of the mounting bracket 130.

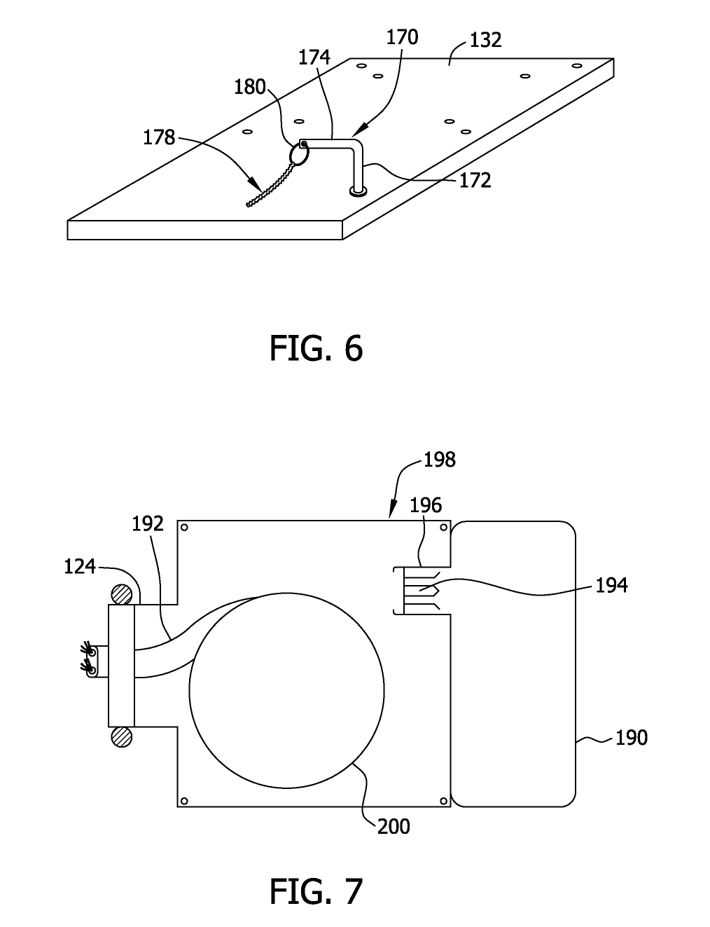

The trigger actuator 170, as best seen in FIGS. 4 and 6, includes a vertical portion 172 extending upwardly from the base plate 132 and a horizontal portion 174 which extends generally perpendicularly from the vertical portion 172. The trigger actuator 170 is rotatably coupled to the base plate 132 with a bearing or other suitable structure. The trigger actuator 170 is configured to rotate about an axis coincident with a longitudinal axis of the vertical portion 172 between a first position and a second position. The first position is an initial resting position where the horizontal portion 174 of the trigger actuator 170 does not actuate the trigger of tool 110 positioned in the mounting bracket 130. The trigger actuator 170 may be biased with a spring or other equivalent structure in the first position. The second position of the trigger is a position in which the horizontal portion 174 of the trigger actuator 170 acts against (i.e., actuates) the trigger of the tool 110 positioned in the mounting bracket 130.

The trigger actuator 170 may be moved from the first position to the second position by a cord, rod, linkage, rope, or other equivalent structure coupled to the trigger actuator. In one embodiment, a cord 178 (FIGS. 1 and 2) is coupled at a first end 180 to the trigger actuator 170 and has a length such that another, second end 182 of the cord 178 can be grasped by a user positioned adjacent the second end 124 of the pole 120. The trigger actuator 170 moves from the first position to the second position when the user pulls the cord 178 and when the user releases the cord 178, the trigger actuator 170 returns to the first position. In some embodiments, the trigger actuator 170 may be fixed in the second position such that it continually actuates the trigger of the tool 110. In these embodiments, a trigger (not shown) may be positioned adjacent the second end 124 of the pole to control actuation of the tool by controlling the flow of electricity to the tool 110.

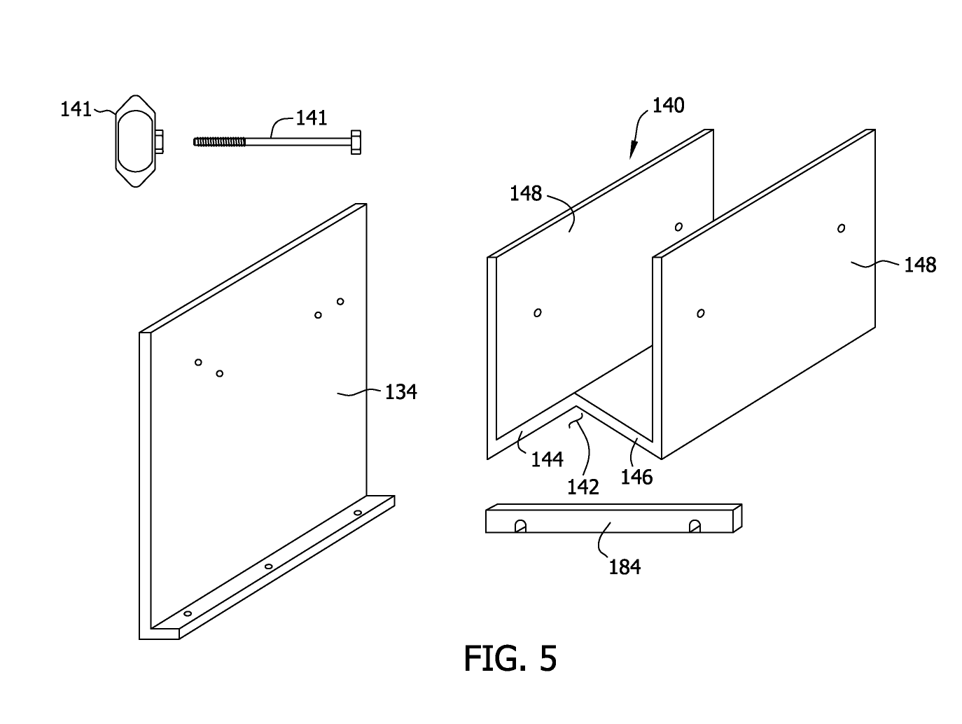

Returning to the mounting bracket 130 shown in FIGS. 3-6, the side plates 134 are generally parallel to each other and extend in a generally perpendicular direction from the base plate 132. The side plates 134 are also generally parallel to a longitudinal axis of the pole 120. The side plates 134 are coupled to the base plate 132 by a plurality of mechanical fasteners 131 in the exemplary embodiment, although in other embodiments the side plates 134 and base plate 132 may be coupled together by any other fastening system. The side plates 134 and the base plate 132 have a plurality of openings formed therein and are sized such that mechanical fasteners can pass therethrough. The plurality of openings in the side plates 134 and the base plate 132 permit the side plates 134 to be positioned in a variety of different positions with respect to the base plate 132 in order to accommodate different types of tools. For example, the plurality of openings in the base plate 132 permit the side plates 134 to be positioned inward from the edges 136 of the base plate 132.

A clamping member 140 is positioned between the side plates 134, as shown in FIGS. 3 and 4. The clamping member 140 is constructed from the same or similar materials as the mounting bracket 130. The clamping member 140 is generally shaped similar to an inverted letter “M” and has a recessed portion 142 formed by a first section 144 and a second section 146. The recessed portion 142 is sized for receiving at least a portion of the tool 110 therein. The clamping member 140 also includes two opposing side members 148, one of which is coupled to the first section 144 of the recessed portion 142 and the other of which is coupled to second section 146 of the recessed portion 142.

The side members 148 of the clamping member 140 are coupled to the side plates 134 of the mounting bracket 130 by mechanical fasteners 141 in the exemplary embodiment. The side members 148 have a plurality of openings formed therein such that the position of the clamping member 140 with respect to the mounting bracket 130 can be readily adjusted to accommodate different tools of varying size. In some embodiments, the side members 148 may not be used and instead the first section 144 and the second section 146 are coupled directly to the side plates 134 of the mounting bracket 130 by mechanical fasteners or other suitable structures. In some embodiments, differently sized clamping members 140 may be provided in order to accommodate differently sized tools. Further, a spacer 184 may be positioned between each of the side members 148 and the side plates 134 in some embodiments.

A battery 190 used to electrically power the tool 110 is positioned adjacent the second end 124 of the pole 120 and is electrically coupled to the tool 110 with wires 192 (FIG. 7) in the exemplary embodiment. In other embodiments, cables or any other suitable electrical connection devices can be used to electrically couple the battery to the tool. The wires 192 may be at least partially disposed within a hollow interior core of the pole 120. A first electrical connector (not shown) is used to couple the wires 192 to the tool 110 and a second electrical connector 194 is used to couple the wires 192 to the battery. A bracket 196 or other suitable device is used to physically couple the battery 190 to a housing 198 positioned adjacent the second end 124 of the pole 120.

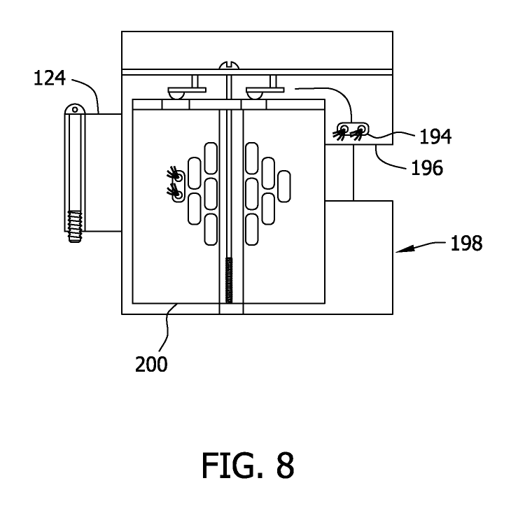

As shown in FIGS. 7 and 8, a cable spool 200 is positioned within the housing 198 adjacent the second end 124 of the pole 120 and is used to store and dispense the wires 192 used to electrically couple the tool 110 to the battery 190. The spool 200 has a spring or other equivalent structure that is used to retract and/or dispense the wires 192 as the length of the pole 120 is changed.

In embodiments where the tool 110 is not battery powered and is instead a corded electrically powered tool, a battery is not used and instead suitable plugs are positioned on the housing 198. One plug may be a female electrical plug (e.g., a standard household electrical socket) configured for coupling to an electrical cord or wires that are in turn coupled to the tool 110. Another plug may be a male plug that is couple to the female plug. Another electrical cord may be used to connect this male plug to an electrical source (e.g., a standard household electrical socket). The male and female plugs are electrically coupled such that electricity can flow from the male plug to the female plug and in turn the tool 110. In embodiments where the tool 100 is a pneumatically or hydraulically powered tool, a hose or other suitable fluid transmission system may be provided to couple the tool 110 to a suitable fluid source (e.g., a source of compressed air or pressurized hydraulic fluid).

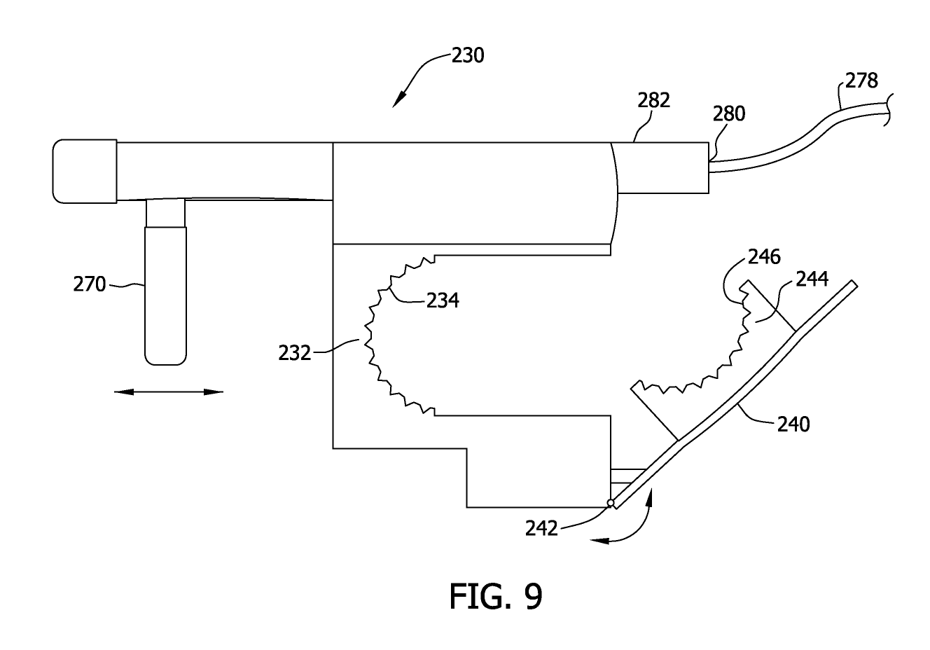

FIG. 9 depicts another embodiment of a mounting bracket (indicated generally at 230) configured for coupling to the first end 122 of the pole 120. Generally, the mounting bracket 230 has a similar function to the mounting bracket 130 described above. That is, the mounting bracket 230 is used to couple the tool 110 to the first end 122 of the pole 120.

The mounting bracket 230 includes a clamping member 240 configured to couple a variety of different tools to the mounting bracket. The mounting bracket 230 is coupled by any suitable fastening system (e.g., mechanical fasteners, adhesive bonding, and/or welding) to the first end 122 of the pole 120. In one embodiment, the mounting bracket 230 and the clamping member 240 are used to couple a handle of the tool 110 to the first end 122 of the pole 120.

The mounting bracket 230 has a curved portion 232 with a plurality of teeth 234 (only one of which is numbered) formed therein. The clamping member 240 is rotatably coupled to the mounting bracket 230 by a hinge 242 or other suitable structure. The clamping member 240 also has a curved portion 244 with a plurality of teeth 246 formed therein.

In a first position as shown in FIG. 9, the clamping member 240 is spaced from the mounting bracket 230 to permit a handle of the tool 110 to placed therebetween. The clamping member 240 is then moved to a second position by rotating it about the hinge 242 in a counter-clockwise direction from the perspective of FIG. 9. In this second position, the teeth 234, 246 of the respective curved portions 232, 244 engage the handle of the tool 110 to couple the tool to the mounting bracket 230. The clamping member 240 is then secured in its second position by any suitable fasteners (not shown). The fasteners may permit the second position of the clamping member 240 to be adjusted (i.e., rotated to varying degrees) in order to permit the mounting bracket 230 and clamping member 240 to receive different tools 110 having differently shaped or sized handles.

In other embodiments, the curved portions 232, 244 do not have any teeth and engage the handle of the tool 110. Alternatively, the curved portions 232, 244 may be lined with a material which aids in gripping the handle of the tool 110, such as a material with a relatively high co-efficient of friction (e.g., rubber, plastic or the like). Such materials also include those with textured surfaces.

The mounting bracket also includes a trigger actuator 270 for actuating a trigger and/or switch used to control operation of the battery-powered tool 110. The trigger actuator 270 is remotely controllable by a user positioned near the second end 124 of the pole 120 with a rope, linkage, or other similar structure. The trigger actuator 270 is slidably coupled to the mounting bracket 230 with any suitable structure. The trigger actuator 270 is configured to slide in a longitudinal direction between a first position and a second position. The first position is an initial resting position where the trigger actuator 270 does not actuate the trigger of the tool 110 positioned in the mounting bracket 230. The trigger actuator 270 may be biased with a spring or other equivalent structure in the first position. In the second position, the trigger actuator 270 acts against (i.e., actuates) the trigger of the tool 110 positioned in the mounting bracket 230.

The trigger actuator 270 may be moved from the first position to the second position by a cord, rod, linkage, rope, or other equivalent structure coupled to the trigger actuator. In one embodiment, a cord 278 (a portion of which is shown in FIG. 9) is coupled at a first end 280 to a portion 282 of the trigger actuator 270 protruding from the mounting bracket 230. The cord 278 has a length such that another, second end (not shown) can be grasped by a user positioned adjacent the second end 124 of the pole 120. The trigger actuator 270 moves from the first position to the second position when the user pulls the cord 278 and when released, the trigger actuator 270 returns to the first position. In some embodiments, the trigger actuator 270 may be fixed in the second position such that it continually actuates the trigger of the tool 110. In these embodiments, a trigger (not shown) may be positioned adjacent the second end 124 of the pole to control actuation of the tool 110 by controlling the flow of electricity to the tool 110.

The process described below for mounting (i.e., securing) the tool 110 in the system 100 is exemplary in nature, and as such the order of the steps described herein may be changed without departing from the scope of the embodiments. Moreover, while the process described below references usage of the mounting bracket 130 and its associated components, the mounting bracket 230 and its associated components may be used instead.

The system 100 described above is used by first mounting the tool 110 in the clamping member 140 and mounting bracket 130. Mechanical fasteners are used to couple the clamping member 140 and mounting bracket 130 together such that the tool 110 is retained securely between the two. The trigger actuator 170 is then positioned adjacent the trigger of the tool 110 such that when in its first position the trigger actuator 170 does not actuate the trigger of the tool. The trigger actuator 170 is also positioned such that when in its second position the trigger actuator 170 actuates the trigger of the tool 110. The first end 180 of the cord 178 is then coupled to the trigger actuator 170 and the second end 182 of the cord 178 is positioned adjacent the second end 124 of the pole 120.

The battery 190 may be removed from the tool 110 before or after it is mounted in the clamping member 140 and mounting bracket 130. After the battery 190 is removed, the first electrical connector is coupled to the one or more battery terminals used to electrically couple the battery to the tool 110 during normal operation. The battery 190 is then coupled with the bracket 196 to the housing 198 positioned adjacent the second end 124 of the pole 120 and electrically coupled to the wires 192 with the second electrical connector 194. In some embodiments, the battery 190 is not removed from the tool 110 and remains in place adjacent the tool 110 during operation of the system 100.

The tool 110 and system 100 are then operated by a user grasping and pulling the second end 182 of the cord 178 which moves the trigger actuator 170 from the first position to the second position. When in the second position, the trigger actuator 170 actuates the trigger of the tool 110, thus initiating operation of the tool 110. To cease operation of the tool 110, the user releases the second end 182 of the cord 178. The trigger actuator 170 then returns to its first position where it does not actuate the trigger of the tool 110 and thus operation of the tool 110 ceases.

The system 100 described herein thus permits a user to couple a standard battery-powered tool 110 to the extension pole 120 to extend the reach of the user. For example, in order to act upon an object positioned above the user, the user may use the system 100 to couple the tool 110 to the pole 120 such that the user can act upon the object with the tool. The user thus is not required to climb a ladder or other structure to position themselves nearer the object. The system also enables users to act upon objects with the tool 110 that are positioned horizontally away from and/or vertically beneath the user. For example, a user utilizing the system 100 could act upon an object positioned in a trench with the tool 110 without positioning themselves in the trench. After using the tool 110 with the system 100, the user may remove the tool 110 from the system 100 and use the tool 110 for standard purposes where the extended reach of the system 100 is not needed.

Exemplary embodiments of a system for coupling a power tool to an extension pole are described above in detail. The system is not limited to the specific embodiments described herein, but rather, components of the system may be utilized independently and separately from other components described herein. Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An extension pole system for receiving a plurality of different power tools, said system comprising:
an extension pole having a first end and a second end;
a mounting bracket coupled to the first end of said extension pole, said mounting bracket having a base plate; and
a clamping member releasably couplable to said mounting bracket to secure a power tool between at least said clamping member and the mounting bracket, where at least one of said mounting bracket and said clamping member are adjustable for receiving a plurality of different power tools.

2. A system in accordance with claim 1, further comprising a trigger actuator rotatably coupled to the base plate of said mounting bracket.

3. A system in accordance with claim 2, wherein said trigger actuator is rotatable between a first position where said trigger actuator does not actuate a trigger of the power tool secured between said clamping member and the base plate and a second position where said trigger actuator actuates the trigger of the power tool secured between said clamping member and the mounting bracket.

4. A system in accordance with claim 1, wherein the power tool is a battery-powered tool and a battery used to power the power tool is positioned adjacent the second end of said pole and is coupled to the power tool by one or more electrical connection devices.

5. A system in accordance with claim 1, further comprising a trigger actuator slidably coupled to said mounting bracket.

6. A system in accordance with claim 5, wherein said trigger actuator is slidable between a first position where said trigger actuator does not actuate a trigger of the power tool secured between said clamping member and said mounting bracket and a second position where said trigger actuator actuates the trigger of the power tool secured between said clamping member and the mounting bracket.

7. A system in accordance with claim 1, wherein said clamping member is rotatable between a first position where the power tool is able to be placed between said clamping member and said mounting bracket and a second position where the power tool is secured between said mounting bracket and said clamping member.

8. A system in accordance with claim 7, wherein said mounting bracket has a curved portion and said clamping member has a curved portion, and wherein said curved portions engage a handle of the power tool when said clamping member is in the second position.

9. A system in accordance with claim 8, wherein at least one of said curved portion of said clamping member and said curved portion of said mounting bracket have teeth formed therein.

10. A system in accordance with claim 7 further comprising a hinge rotatably coupling said clamping member to said mounting bracket.

11. A system in accordance with claim 4 further comprising one or more wires electrically coupling the battery positioned adjacent the second end of said pole to the power tool secured by said clamping member to said mounting bracket.

12. A system in accordance with claim 11 further comprising a spool to store and/or dispense said wires, said spool positioned adjacent the second end of said pole.

13. A pole system for receiving a plurality of different tools, said system comprising:
a pole having a first end and a second end;
a mounting bracket coupled to the first end of said pole;
a clamping member releasably couplable to said mounting bracket to secure a tool between at least said clamping member and said mounting bracket, wherein said mounting bracket and said clamping member are adjustable for receiving a plurality of different tools.

14. A system in accordance with claim 13 wherein said pole is a telescoping pole and includes a plurality of sections such that the length of said pole can be adjusted.

15. A system in accordance with claim 13 further comprising a trigger actuator rotatably coupled to said mounting bracket, wherein said trigger actuator is rotatable between a first position where said trigger actuator does not actuate a trigger of the tool secured between said clamping member and the base plate and a second position where said trigger actuator actuates the trigger of the tool secured between said clamping member and the mounting bracket.

16. A system in accordance with claim 15 further comprising a spring for biasing said trigger actuator in the first position.

17. A system in accordance with claim 13 further comprising a trigger actuator slidably coupled to said mounting bracket, wherein said trigger actuator is slidable between a first position where said trigger actuator does not actuate a trigger of the power tool secured between said clamping member and the base plate and a second position where said trigger actuator actuates the trigger of the tool secured between said clamping member and the mounting bracket.

18. A system in accordance with claim 17 further comprising a spring for biasing said trigger actuator in the first position.

19. A method of securing a tool in a pole system for receiving a plurality of different tools, the system comprising a pole having a first end and a second end, a mounting bracket coupled to the first end of the pole, and a clamping member releasably couplable to the mounting bracket to secure the tool between at least the clamping member and the mounting bracket, wherein the at least one of the clamping member and the mounting bracket are adjustable to received a plurality of different tools, said method comprising the steps of:
mounting the tool in the clamping member and the mounting bracket;
positioning a trigger actuator connected to the mounting bracket against a trigger of the tool, wherein the trigger actuator is positionable between a first position where the actuator does not actuate the trigger of the tool and a second position where the actuator acts against the trigger; and
pulling a cord coupled to the trigger actuator, wherein pulling of the cord moves the trigger actuator to the second position and the actuator acts against the trigger of the tool to actuate the tool.

20. A method in accordance with claim 19 further comprising positioning a battery for powering the tool adjacent a second end of the pole and electrically coupling the battery to the tool.
